(19) United States
(12) Patent Application Publication
(10) Pub. No.: US 2026/0231537 A1
(43) Pub. Date: Aug. 6, 2026

(54) AN OPTICAL STRUCTURE FOR ENHANCING THE EFFICIENCY OF A SOLAR CELL

(71) Applicant: ICS INTELLIGENT CONTROL SYSTEMS LTD OY, Helsinki (FI)

(72) Inventors: Kari RINKO, Helsinki (FI); Tero TUOHIOJA, Oulu (FI); Andrea PFREUNDT, Triberg im Schwarzwald (DE)

(21) Appl. No.: 19/150,424

(22) PCT Filed: Jan. 24, 2024
(86) PCT No.: PCT/FI2024/050030

§ 371 Date: Jul. 23, 2025

Related U.S. Application Data
(60) Provisional application No. 63/481,259, filed on Jan. 24, 2023.

(51) Int. Cl. H10F 19/35; H10F 77/30; H10F 77/42

(52) U.S. Cl. CPC H10F 19/35; H10F 77/315; H10F 77/484; H10F 77/488

(57) ABSTRACT

An optical structure, wherein a first area of a solar cell, said first area being a less active edge area of the solar cell, is at least partially covered by an overlapping optical layer element, wherein said overlapping optical layer structure is configured to at least partially redirect light originally directed towards the first area, wherein the redirected light is to be at least partially directed towards a second area, optionally including center area, of the solar cell, wherein said second area is a more active area than the first area, thereby preferably providing, due to enhanced light conversion efficiency, more energy and improved total gain in the solar cell or module comprising the solar cell. A method for enhancing the efficiency of a solar cell or a related module and a method for manufacturing an optical structure is further provided.

### TECHNICAL FIELD OF THE INVENTION

The invention relates to optical structures in general. More specifically, the invention relates to an optical structure where a first area of a solar cell is at least partially covered by an overlapping optical layer element.

### BACKGROUND OF THE INVENTION

Different PV (photovoltaic) cells have variable efficiency curves on the edge area, wherein various aspects such as different edge configurations with and without conductive layers, conductors, fingers, passivation, etc. have influence on inactive cell edge area and total loss of full area by edge recombination. Especially silicon heterojunction cells (SHJ/HTJ) and n-type silicon cells such as TopCon and others have insufficient edge configurations and inefficient (less active) edge area, but still also other cell types, such as p-type silicon cells typically have at least small inactive or at least less active edge area.

There are different factors for efficiency loss in full size and cut size cells. A number of solutions have been suggested to improve these losses including a) cell overlapping or shingle configuration, b) better control of conductive layer on the edge with conductive finger position, c) edge passivation, d) improved edge cutting, and e) improved uniformity of cell coating. All those are not resolving the total loss and there are not yet real industrial solutions and several challenges with negative impact for yield and cost are still available.

One typical module (several connected photovoltaic cells) configuration is to utilize an overlapping cell design, wherein one cell edge is covered by another cell edge. This solution hiding one less efficient cell edge, but leaving other edges visible, thus less efficient edge areas still reducing the total energy gain. There is also a shingle configuration, wherein every second cell is on top of neighbor cells, but this overlapping cell still has all visible edges, thus this solution does not fully resolve the inactive edge area issue either. Also, both module configurations are more critical to produce modules with high yield, thus many module manufacturers already decided to stop these module configurations.

Another optional solution is to utilize edge passivation process for inactive cell edge area in order to minimize edge recombination loss. This has been very much investigated, while not yet realized in actual production. There is a need to develop a new production method with good yield. There is no existing fully satisfactory solution for the purpose yet.

Edge recombination can be minimized also by a conductive finger grid on the top of a cell, which should be a bit further away from the edge area, and a lateral conductive layer, such as transparent conductive oxide(s) (TCO) or other comparable conductive layer to be controlled on the edge area; e.g., a uniform layer covers the whole surface or leaves the edge area without it. However, these optimizations are not sufficient to replace the edge recombination or resolve the inactive edge area.

### SUMMARY OF THE INVENTION

An object of the invention is to alleviate at least some of the problems in the prior art. In accordance with one aspect of the present invention an optical structure is provided, wherein a first area of a solar cell, said first area being a less active edge area of the solar cell, is at least partially covered by an overlapping optical layer element, wherein said overlapping optical layer structure is configured to at least partially redirect light originally directed towards the first area, wherein the redirected light is to be at least partially directed towards a second area, optionally including center area, of the solar cell, wherein said second area is a more active area than the first area, thereby preferably providing, due to enhanced light conversion efficiency, more energy and improved total gain in the solar cell or module comprising the solar cell.

Various embodiments of the present invention provide a new optical booster solution in the form of e.g., an arrangement (structure) and a method for addressing the above-mentioned inactive or less active cell edge area and efficiency loss associated therewith. A less active edge area of a solar cell, or PV cell, may thus be at least partially covered by an overlapping optical element incorporating or substantially being an optical layer or optical layer structure, which redirects the incident light from the first, edge area towards the more active second area of the cell, typically being a center area, providing enhanced light conversion efficiency with more energy and improving the total gain in the associated solar cell or module. This solution is simple to implement, yields power gains on the module and is easily integrated in various module configurations.

The overlapping optical layer structure being configured to redirect incident light from the first area to the second area may refer to the overlapping optical layer structure e.g. reflecting and/or transmitting at least a portion of light that is originally directed from the environment towards a first location residing on the first area so that the light is being redirected towards another direction and a second location that is different from the first location. The redirected light may be reflected from the overlapping optical layer structure e.g. towards a further element such as glass element, from which the light may be further reflected and then directed towards the second area of the solar cell. Additionally or alternatively, at least a portion of the light originally directed towards the first location may be transmitted through the overlapping optical layer structure and optionally refracted so as to be directed to the first or a further location on the solar cell. This may also increase the overall gain or effectiveness of the solar cell.

The suggested configuration of the overlapping optical layer element may improve solar cell module efficiency even in narrow cell gaps when using e.g., HJT, SHJ and other solar cell types with wide, less efficient edge regions.

The function of the overlapping optical layer element may be based on reflection, refraction, transmission, diffusion diffraction or any combination of such.

The overlapping optical layer element may be formed by or comprise optical patterns, such as embedded cavity-optics optionally including air or other gaseous cavities.

The overlapping optical layer element may be formed by or comprise optical patterns, combination of materials with variable refractive indexes, and/or reflective coatings.

The material of the overlapping optical layer element may comprise or be based on preferably transparent polymer(s), thermoplastic or thermoset resin(s), glass or ceramic material(s), and/or combination of different layers, potentially including non-transparent coating(s).

The material of the overlapping optical layer element may comprise or be based on non-transparent material, optionally comprising a metal coating.

The overlapping optical layer element may comprise or include a film such as a tape or other type of a film that is positioned between cell and string spacing including module edge areas and interconnection regions, wherein it is overlapping the cell edge areas as described herein elsewhere. Film or tape width can be about 1 mm up to several millimeters, for instance. For example, a so-called SEO (Solar Energy Optics) film may be utilized.

One preferred overlapping optical layer element is or comprises a partially reflective and partially transmissive film, which can be optimized for edge efficiency profile with optimal (optimized as desired/selected) redirection and transmission capabilities in order to achieve the maximum gain value in each edge region. E.g., optical pattern density in the overlapping optical layer element may be configured to at least locally gradually or linearly change (increase or decrease) and optimize the redirected and transmitted light on the cell surface depending on the type of PV cell and its edge efficiency profile (increase or decrease from the edge of the cell), for example. Also, transmitted light can be controlled by different optical solutions. This has a positive impact for different incident angles of light in order to capture maximum amount of light for energy conversion on the surface of PV cells.

The overlapping optical layer structure (e.g., a film or specifically, a tape, for instance) may be easily integrated in various module configurations. The overlapping optical layer element may be pre-prepared and provided with e.g., adhesive. Alternatively, it may be prepared in-situ.

The overlapping optical layer structure, or at least a film of the overlapping optical layer structure, may be applied on the inner surface of a top glass by optically clear adhesive (OCA), EVA (ethyl vinyl acetate), optical hotmelt, etc.

The overlapping optical layer structure can also be on the top of cell surface e.g., by EVA or other adhesive, especially on the cell edge area and overlapping eg. two different string lines. Applying this overlapping optical layer structure on top of the cell surface, edge area of the cells, between string or cell spacing or cells and interconnections. This provides additional benefit among mentioned power gain, the cell matrix and string line alignment can be fixed by applied overlapping optical layer structure with included adhesive to support module manufacturing and lamination and the final yield by preventing cell matrix and string lines movement during the manufacturing process. There is no need to use additional fixing tape. In the figure herein is presented a cell adhered overlapping optical layer structure, tape. Additionally, the overlapping optical layer structure may be applied on the encapsulant layer, which could be EVA, POE, TPO, etc. The overlapping optical layer structure can be utilized also on the rear side of the cell, especially if the module has e.g., rear glass and sufficient amount of light can be attained from that side as well, e.g., (vertically installed) module wall, wherein bifacial PV cells can have similar gain benefit as on the front side of the module.

The overlapping optical layer structure contemplated herein offers a highly attractive solution to improve power output and efficiency of PV modules. The utility of the present solution is also in introducing an economical alternative for demanding edge passivation or shingle cell configurations in connection with PV modules. Yet, the present invention enables to utilize cell gaps, which can be covered by optical film/tape including cell edge overlapping, wherein edge passivation and shingle cell configurations are not needed.

The present invention also relates to use of an overlapping optical layer element preferably comprising a film as at least partially overlapping a first, edge area of a solar cell, for at least partially redirecting light originally directed to the first area, wherein said redirected light is to be directed towards at least a second, preferably more active area such as a center area of the solar cell.

A method for enhancing the efficiency of a solar cell or a related module is also provided, the method comprising at least partially covering a first, edge area of a solar cell by an overlapping optical layer element configured to redirect light originally directed to the first area, wherein the redirected light is to be at least partially directed towards a selected second, preferably more active area, optionally including center area, of the solar cell, thereby preferably providing, during operation and due to the enhanced better light conversion efficiency, more energy and improved total gain for the solar cell or module comprising the cell.

The invention also relates to a method for manufacturing an optical structure, the method comprising providing a string of solar cells and providing at least one overlapping optical layer element to at least partially cover a first, edge area of at least a first solar cell and a first, edge area of at least a second, adjacent solar cell of the string of solar cells, wherein the overlapping optical layer element is configured to redirect light originally directed to the first areas of each of the solar cells, wherein the redirected light is to be at least partially directed towards selected second, preferably more active areas, optionally including center areas, of the respective solar cells.

Providing of the overlapping optical layer element may comprise attaching the overlapping optical layer element to the surfaces of the first and second solar cells with an adhesive to stabilize cell matrix and string line positions during manufacturing of the structure.

The exemplary embodiments presented in this text are not to be interpreted to pose limitations to the applicability of the appended claims. The verb “to comprise” is used in this text as an open limitation that does not exclude the existence of unrecited features. The features recited in depending claims are mutually freely combinable unless otherwise explicitly stated.

The novel features which are considered as characteristic of the invention are set forth in particular in the appended claims. The invention itself, however, both as to its construction and its method of operation, together with additional objects and advantages thereof, will be best understood from the following description of specific example embodiments when read in connection with the accompanying drawings.

### BRIEF DESCRIPTION OF THE DRAWINGS

Next the invention will be described in greater detail with reference to exemplary embodiments in accordance with the accompanying drawings, in which:

FIG. 1 SHOWS ONE EXAMPLE OF AT LEAST A PORTION OF AN OPTICAL STRUCTURE,

FIG. 2 illustrates one example of at least a portion of an optical structure,

FIG. 3 shows efficiency of a solar cell as a function of distance from an edge of the solar cell, and

FIG. 4 exhibits solar cell powers, associated gains, and Watt peak/module relating to a module of solar cells,

FIG. 5 shows efficiency of solar cells as a function of distance from an edge of the solar cell relating to a module of solar cells,

FIG. 6 shows calculations for module power and added gain for an optical structure provided as a module with different string/cell spacings and provided overlapping optical layer elements at different film overlaps, and

FIG. 7 shows comparison of shingle configuration PV module with a PV module that may be provided according to the invention as an optical structure with optimized solar cell 102 spacing and associated overlapping optical layer element 104.

### DETAILED DESCRIPTION

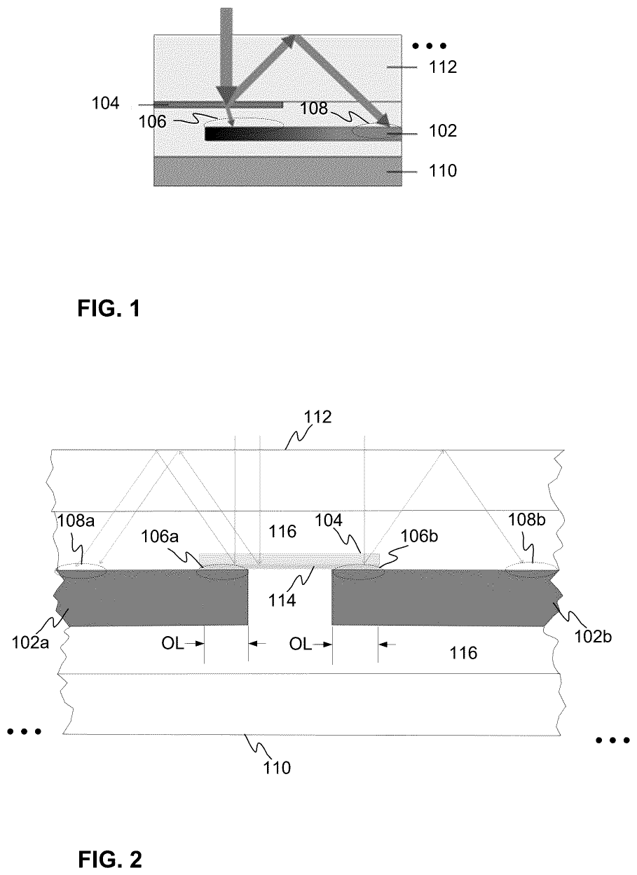

FIG. 1 shows one example of at least a portion of an optical structure. The optical structure comprises at least one solar cell 102. The optical structure further comprises at least one overlapping optical layer element 104. It should be noted that FIG. 1 illustrates only a portion of the optical structure and the structure continues at the right hand side.

The overlapping optical layer element 104 at least partially covers the solar cell 102. The optical layer element 104 at least partially covers a first area 106 (illustrated schematically in FIG. 1) of the solar cell 102. The first area 106 corresponds to an edge area of the solar cell 102 surface where the first area is less active or less efficient than another area of the solar cell 102. The first area 106 may be less efficient than another area of the solar cell 102 in converting light to electricity.

The optical layer element 104 may contact the surface of the solar cell 102 or the optical layer element 104 may be applied to the surface of the solar cell 102 by using e.g. adhesive.

The overlapping optical layer element 104 is configured to redirect at least a portion of light that is originally directed towards the first area 106 such that the redirected light is to be at least partially directed towards a second area 108 of the solar cell 102. The second area 108 may be a center area of the solar cell 102. The second area 108 is an area of the solar cell 102 that is more active or more efficient (may convert light into energy more efficiently) than the first area 106 of the solar cell 102. Redirecting of the light to the second area 108 may be carried out by the overlapping optical layer element 104 or the overlapping optical layer element 104 may redirect light incident on the first area 106 to another element of the structure, which then further redirects the light to the second area 108.

The overlapping optical layer element 104 may additionally or alternatively redirect at least a portion of the light originally directed towards a first location in the first area 106 to at least a second location on the first area 106.

The overlapping optical layer element 104 may thus reflect and/or transmit light, as also depicted in FIG. 1. Preferably, most of the light is reflected and redirected away from inactive edge area 106 towards more efficient cell surface area. Part of the light can be transmitted to the cell surface (see the small arrow through the overlapping optical layer element (film), which may also increase the overall gain.

The function of the overlapping optical layer element 104 may be based on reflection, refraction, transmission, diffusion, diffraction or any combination of the aforesaid optical functions, which may be achieved by included optical patterns, such as embedded cavity-optics including air-cavities (or other gaseous cavities if not void cavities) and/or optical material combination(s) of variable refractive indexes or reflective coatings, for instance.

The material of the overlapping optical layer element 104 may comprise or be based on preferably transparent polymer(s), thermoplastic or thermoset resin(s), glass or ceramic material(s), and/or combination of different layers, potentially including non-transparent coating(s) or material(s), such as metal coating(s) etc.

The overlapping optical layer element 104 preferably comprises or is a film or tape element, e.g. SEO film.

The optical structure may comprise or be provided on a backsheet 110.

The optical structure may further comprise or be coupled with a top glass 112.

The overlapping optical layer element 104 may be provided as being applied on the surface of the solar cell 102 or on the inner surface of the top glass 112, for example.

FIG. 2 shows an example of at least a portion of an optical structure. The structure of FIG. 2 may continue in both right- and left-hand directions. The optical structure of FIG. 2 may also be a module comprising solar cells. FIG. 2 shows a portion of an optical structure which may comprise a string of solar cells comprising at least a first solar cell 102a and second solar cell 102b.

An overlapping optical layer element 104 is then configured to at least partially cover a first, edge area 106a of at least a first solar cell 102a and a first, edge area 106b of at least a second, adjacent solar cell 102b of the string of solar cells. The overlapping optical layer element 104 is configured to redirect light originally directed to the first areas 106a, 106b of each of the solar cells 102a, 102b. The redirected light is to be at least partially directed towards at least a second area 108a of the first solar cell 102a and a second area 108b of the second solar cell 102b.

The structure may comprise at least one overlapping optical layer element 104. The overlapping optical layer element 104 covers at least a first area106a of the first solar cell 102a and first area 106b of the second solar cell 10b. The second areas 108a, 108b are more active than the first (edge) areas 106a, 106b.

In connection with any optical structure, the overlapping optical layer element 104 may be configured to overlap an edge area of the associated solar cell 102a, 102b, where the overlap along the surface of the first area 106 of the solar cell 102a, 102b or the “film overlap” corresponds to a distance OL from the edge of the solar cell 102a, 102b. The film overlap OL may be selected based on the use case. The film overlap OL may vary between solar cells 102a, 102b in the same optical structure.

The overlapping optical layer element 104 may be applied to the surface of the first solar cell 102a and second solar cell 102b by using an adhesive layer 114.

The optical structure may comprise or be provided on a backsheet or rear glass 110.

The optical structure may further comprise or be coupled with a top glass 112.

The optical structure may comprise or be provided with an encapsulant 116.

It may be noted that the overlapping optical layer element 104 may also be provided elsewhere in the optical structure as disclosed hereinbefore.

However, when the overlapping optical layer element 104 is applied to a string of solar cells so as to at least partially cover also the cell or string spacing, the cell matrix and string line positions during manufacturing of the structure may be stabilized.

FIG. 3 shows efficiency of a solar cell 102 as a function of distance from an edge of the solar cell 102. As shown in Fog. 3, experimental data from silicon heterojunction half cells tests show an efficiency drop towards the cell edge (“fitted efficiency from measurement”). Utilizing the invention, as seen from the curve “calculated effective efficiency with overlapping optical layer element”, it is seen that with the overlapping optical layer element 104 on the first, edge area 106 on the PV cell 102 provides improved gain, which enhances the total solar cell and module efficiency. The upper curve (“calculated effective efficiency with overlapping optical layer element”) section with a flattened slope in the figure illustrates this enhancement of efficiency.

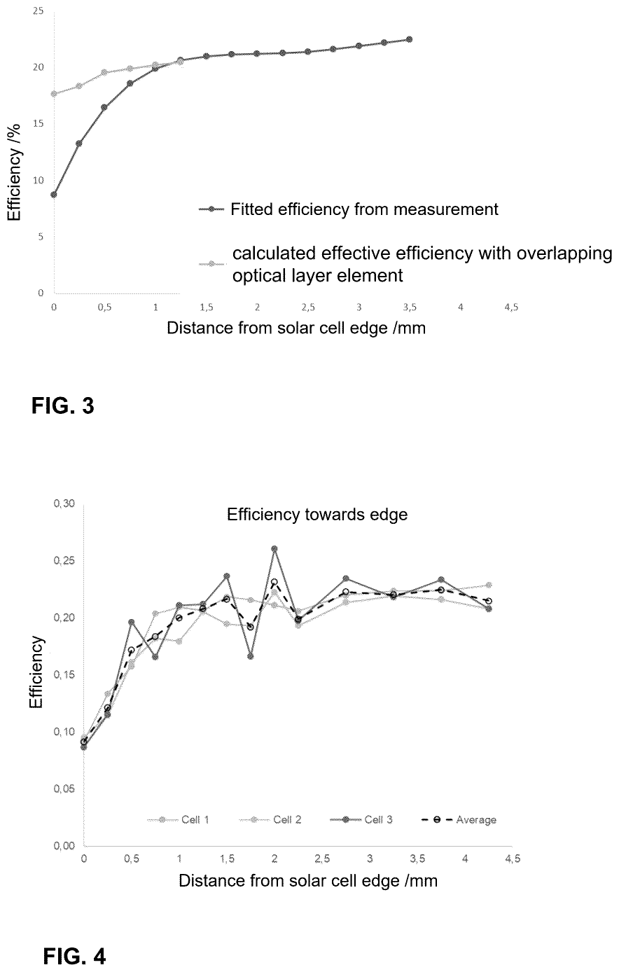

FIG. 4 shows efficiency of solar cells 102 as a function of distance from an edge of the solar cell relating to a module of solar cells 102 comprising a plurality of solar cells 102. Efficiency is shown for three solar cells 102 separately and also an average is given.

Optimized module efficiency can be obtained, when PV cell edge efficiency profile is measured, e.g., with shadow masking method on the edge/first area 106. Once the efficiency profile is available, the ideal overlapping optical layer element 104 pattern and its density or specifically film overlap distance OL can be calculated.

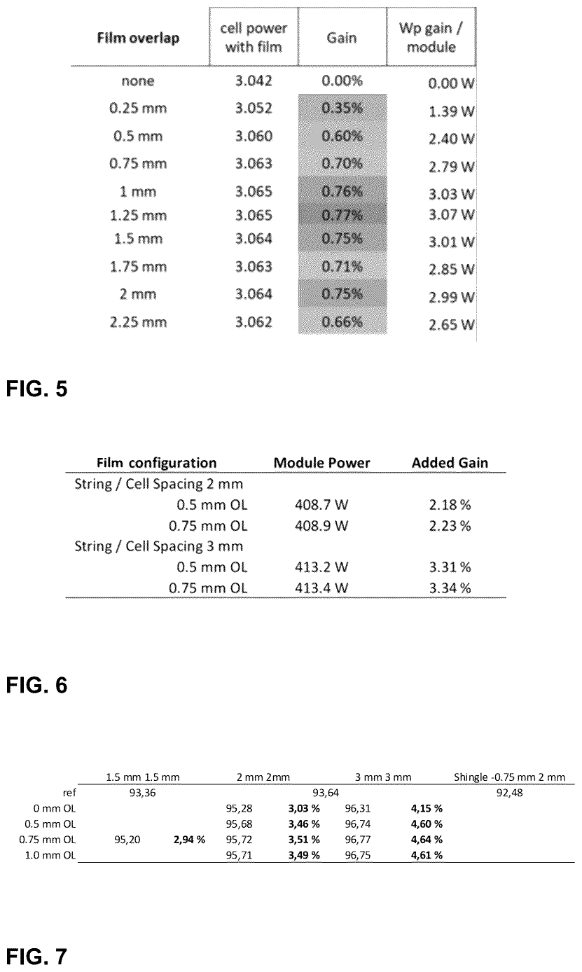

FIG. 5 exhibits solar cell powers, associated gains, and Watt peak gain per module relating to a module of solar cells comprising the solar cells 102 with different film overlaps D. It can be seen that a selected film overlap OL may lead to selected or optimized gain. A film overlap OL of e.g. about 1 mm-2 mm may be advantageous.

The final module optimization can be continued after film overlap OL optimization. The overlapping optical layer element (e.g., film or specifically, tape) width can be considered together with solar cell 102 and string spacing on the module. FIG. 6 shows, by way of example, calculations for module power and added gain for an optical structure provided as a module with different string/cell spacings and provided overlapping optical layer elements 104 at different film overlaps OL. The calculations are for a 400 Wp HJT module, with reference module with 2 mm cell and string gaps and also module with 3 mm cell and string gaps, which shows enhanced added gain.

When comparing shingle configuration PV module with a PV module that may be provided according to the invention as an optical structure with optimized solar cell 102 spacing and associated overlapping optical layer element 104, the improved gain can be realized as presented in FIG. 7.

In a method for enhancing the efficiency of a solar cell 102 or a related module comprising a plurality of solar cells 102, the method may comprise at least partially covering a first, edge area 106 of a solar cell by an overlapping optical layer element 104 configured to redirect light originally directed to the first area, wherein the redirected light is to be at least partially directed towards a selected second, preferably more active area 108, optionally including center area, of the solar cell 102, thereby preferably providing, during operation and due to the enhanced better light conversion efficiency, more energy and improved total gain for the solar cell 102 or module comprising the cell 102.

A method for manufacturing an optical structure may comprise providing a string of solar cells comprising at least a first solar cell 102a and second solar cell 102b. The method additionally comprises providing at least one overlapping optical layer element 104 to at least partially cover a first, edge area 106a of at least the first solar cell 102a and a first, edge area 106b of at least the second, adjacent solar cell 106b of the string of solar cells. The overlapping optical layer element 104 is configured to redirect light originally directed to the first areas 106a, 106b of each of the solar cells 102a, 102b, wherein the redirected light is to be at least partially directed towards selected second, preferably more active areas 106a, 106b, optionally including center areas, of the respective solar cells 102a, 102b.

Providing of the at least one overlapping optical layer element 104 may comprise attaching the overlapping optical layer element 104 to the surfaces of the first and second solar cells 102a, 102b with an adhesive to stabilize cell matrix and string line positions during manufacturing of the structure.

Considering a module with a string of solar cells 102a, 102b, at least a portion of the solar cells 102a, 102b may be provided with an associated overlapping optical layer element 104. Also, all cells 102a, 102b of the string of solar cells may be provided with at least one (or a plurality of) associated overlapping optical layer elements 104.

The present invention and related overlapping optical layer element 104 provided e.g. as film/tape with selected film overlap OL may provide additional power gain and stabilize the module or optical structure power and quality by reducing the cost of module/structure manufacturing, especially replacing the need of edge passivation, replacing the most advance cell cutting technique, stabilize the cell matrix and string line positions. It can stabilize edge area gain, which can vary or change during outdoor use (ref. damp heat reduced gain on the edge of the cell). The overlapping optical layer element 104 is stable under outdoor use and does not cause any gain loss. The overlapping optical layer element 104 may cover an inefficient and unstable edge area of the PV cell 102 and stabilize the function of the module. This overlapping optical layer element 104 is suitable to cover all kinds of inefficient and unstable areas and spacing in order to provide improved power gain associated with a module.

The invention has been explained above with reference to the aforementioned embodiments, and several advantages of the invention have been demonstrated. It is clear that the invention is not only restricted to these embodiments, but comprises all possible embodiments within the spirit and scope of inventive thought and the following patent claims.

The features recited in dependent claims are mutually freely combinable unless otherwise explicitly stated.

1. An optical structure, wherein a first area of a solar cell, said first area being a less active edge area of the solar cell, is at least partially covered by an overlapping optical layer element, wherein said overlapping optical layer structure is configured to at least partially redirect light originally directed towards the first area, wherein the redirected light is to be at least partially directed towards a second area, optionally including center area, of the solar cell, wherein said second area is a more active area than the first area, thereby preferably providing, due to enhanced light conversion efficiency, more energy and improved total gain in the solar cell or module comprising the solar cell.

2. The structure of claim 1, wherein the function of the overlapping optical layer element is based on reflection, refraction, transmission, diffusion diffraction or any combination of such.

3. The structure of any preceding claim, wherein the overlapping optical layer element is formed by or comprises optical patterns, such as embedded cavity-optics optionally including air or other gaseous cavities.

4. The structure of any preceding claim, wherein the overlapping optical layer element is formed by or comprises optical patterns, combination of materials with variable refractive indexes, and/or reflective coatings.

5. The structure of any preceding claim, wherein the material of the overlapping optical layer element comprises or is based on preferably transparent polymer(s), thermoplastic or thermoset resin(s), glass or ceramic material(s), and/or combination of different layers, potentially including non-transparent coating(s).

6. The structure of any preceding claim, wherein the material of the overlapping optical layer element comprises or is based on non-transparent material, optionally comprising a metal coating.

7. The structure of any preceding claim, wherein the overlapping optical layer element comprises a film or specifically, a tape, between the solar cell and string spacing including module edge areas and interconnection regions, wherein it is overlapping cell edge areas.

8. The structure of any preceding claim, wherein the overlapping optical layer element comprises or is a partially reflective and partially transmissive film, which may be optimized for PV cell edge efficiency profile with optimal (optimized as desired/selected) redirection and transmission combination in order to achieve the maximal gain value is each edge region.

9. The structure of any preceding claim, wherein the optical pattern density in the overlapping optical layer element is configured to at least locally gradually or linearly increase or decrease.

10. Use of an overlapping optical layer element preferably comprising a film as at least partially overlapping a first, edge area of a solar cell, for at least partially redirecting light originally directed to the first area, wherein said redirected light is to be directed towards at least a second, preferably more active area such as a center area of the solar cell.

11. A method for enhancing the efficiency of a solar cell or a related module comprising at least partially covering a first, edge area of a solar cell by an overlapping optical layer element configured to redirect light originally directed to the first area, wherein the redirected light is to be at least partially directed towards a selected second, preferably more active area, optionally including center area, of the solar cell, thereby preferably providing, during operation and due to the enhanced better light conversion efficiency, more energy and improved total gain for the solar cell or module comprising the cell.

12. A method for manufacturing an optical structure, the method comprising providing a string of solar cells and providing at least one overlapping optical layer element to at least partially cover a first, edge area of at least a first solar cell and a first, edge area of at least a second, adjacent solar cell of the string of solar cells, wherein the overlapping optical layer element is configured to redirect light originally directed to the first areas of each of the solar cells, wherein the redirected light is to be at least partially directed towards selected second, preferably more active areas, optionally including center areas, of the respective solar cells.

13. The method of claim 12, wherein providing the overlapping optical layer element comprises attaching the overlapping optical layer element to the surfaces of the first and second solar cells with an adhesive to stabilize cell matrix and string line positions during manufacturing of the structure.
